(19) United States
(12) Patent Application Publication
(10) Pub. No.: US 2024/0304593 A1
(43) Pub. Date: Sep. 12, 2024

(54) DIRECT BONDING METHODS AND STRUCTURES

(71) Applicant: ADEIA SEMICONDUCTOR BONDING TECHNOLOGIES INC., San Jose, CA (US)

(72) Inventor: Cyprian Emeka Uzoh, San Jose, CA (US)

(21) Appl. No.: 18/179,126

(22) Filed: Mar. 6, 2023

(51) Int. Cl. H01L 23/00; H01L 25/00; H01L 25/065

(52) U.S. Cl. CPC H01L 24/80; H01L 24/05; H01L 24/06; H01L 24/08; H01L 24/94; H01L 24/97; H01L 25/0657; H01L 25/50; H01L 2224/05647; H01L 2224/06181; H01L 2224/08145; H01L 2224/80009; H01L 2224/80013; H01L 2224/80357; H01L 2224/80379; H01L 2224/80895; H01L 2224/80896; H01L 2224/80906; H01L 2224/94; H01L 2224/97; H01L 2225/06565; H01L 2924/01006; H01L 2924/01014; H01L 2924/04642; H01L 2924/0504; H01L 2924/0544; H01L 2924/05494; H01L 2924/059

(57) ABSTRACT

Disclosed herein are processes and methods for direct bonding. In some embodiments, the process includes providing an element having a dielectric bonding surface and one or more conductive features exposed at the dielectric bonding surface, where the dielectric bonding surface has a planarity suitable for direct bonding. The process also includes, after providing the element, exposing the dielectric bonding surface to the products of a water vapor plasma prior to direct bonding the element.

### BACKGROUND

### Field

The field relates to direct bonding methods and structures.

### Description of the Related Art

Microelectronic elements, such as integrated device dies or chips, may be mounted or stacked on other elements thereby forming a bonded structure. Direct metal bonding can be conducted at low temperatures and without external pressure. For example, direct hybrid bonding involves directly bonding non-conductive features (e.g., inorganic dielectrics) of different elements together, without intervening adhesives, while also directly bonding conductive features (e.g., metal pads or lines) of the elements together. For example, a microelectronic element can be mounted to a carrier, such as a wafer, an interposer, a reconstituted wafer or other element, etc. As another example, a microelectronic element can be stacked on top of another microelectronic element, e.g., a first integrated device die can be stacked on a second integrated device die. Each of the microelectronic elements can have conductive pads for mechanically and electrically bonding the elements to one another. There is a continuing need for improved methods for forming the bonded structure.

### BRIEF DESCRIPTION OF THE DRAWINGS

FIGS. 1A and 1B are schematic side sectional views showing stages of direct bonding according to some embodiments.

FIG. 2 is a flowchart illustrating a bonding process that involves exposing an element to water vapor plasma, according to some embodiments.

FIGS. 3A-3J are schematic side sectional views of elements at various blocks of a wafer-to-wafer bonding process, according to some embodiments.

FIG. 4 is a flowchart illustrating a die-to-wafer bonding process that involves exposing an element to water vapor plasma, according to some embodiments.

FIGS. 5A-5G are schematic side sectional views of elements at various blocks of a die-to-wafer bonding process like that of FIG. 4.

FIG. 6 is a flowchart illustrating a bonding process that involves exposing an element to water and oxygen plasma followed by water vapor plasma, according to some embodiments.

FIG. 7 is a flowchart illustrating a bonding process that involves exposing an element to oxygen plasma and then water vapor plasma, according to some embodiments.

FIG. 8 is a flowchart illustrating a bonding process that involves exposing the backside of a bonded structure to water vapor plasma, according to embodiments.

FIGS. 9A-9D are schematic side sectional views of the bonded structure at various blocks of a bonding process like that of FIG. 8.

FIG. 10 is a flowchart illustrating a bonding process that involves exposing a substrate that includes polymer materials to water vapor plasma, according to embodiments.

FIGS. 11A-11C are schematic side sectional views of semiconductor elements at various blocks of the bonding process shown in FIG. 10.

### DETAILED DESCRIPTION OF THE PREFERRED EMBODIMENT

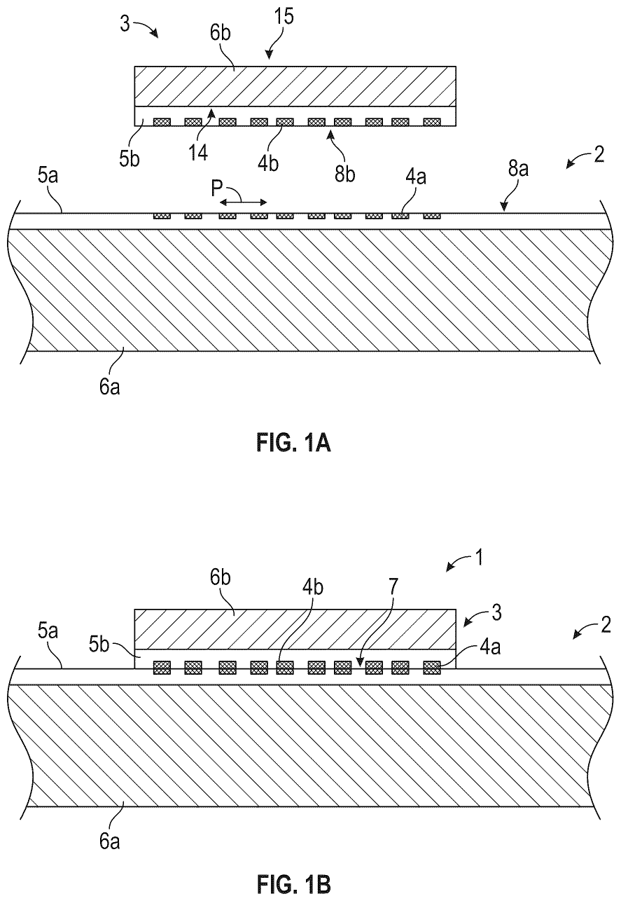

With reference initially to FIGS. 1A and 1B, various embodiments disclosed herein relate to directly bonded structures 1 in which two elements 2, 3 can be directly bonded to one another without an intervening adhesive. While the illustrated embodiment involves direct hybrid bonding of conductive and non-conductive elements, the skilled artisan will appreciate that the advantages and principles taught herein also apply to direct bonding of non-conductive surfaces.

A bonded structure comprises two elements that can be directly bonded to one another without an intervening adhesive. Two or more elements (such as integrated device dies, wafers, passive devices, individual active devices such as power switches, glass substrates, flat panels other microelectronic elements, etc.) 2, 3 may be stacked on or bonded to one another to form a bonded structure 1. Conductive features (e.g., contact pads 4a, traces, exposed ends of vias, or through substrate electrodes or vias) of a first element 2 may be electrically connected to corresponding conductive features (e.g., contact pads 4b) of a second element 3. Any suitable number of elements can be stacked in the bonded structure 1. For example, a third element (not shown) can be stacked on the second element 3, a fourth element (not shown) can be stacked on the third element, etc. Additionally or alternatively, one or more additional elements (not shown) can be stacked laterally adjacent one another along the first element 2. In some embodiments, the laterally stacked additional element may be smaller than the second element. In some embodiments, the laterally stacked additional element may be at least two times smaller than the second element.

In some embodiments, the elements 2, 3 are directly bonded to one another without an adhesive. In various embodiments, a non-conductive field region that includes a non-conductive or dielectric material can serve as a first bonding layer 5a of the first element 2 which can be directly bonded to a corresponding non-conductive field region that includes a non-conductive or dielectric material serving as a second bonding layer 5b of the second element 3 without an adhesive. The non-conductive bonding layers 5a, 5b can be disposed on respective front sides 14 of device portions 6a, 6b, such as a semiconductor (e.g., silicon) portion of the elements 2, 3, or back-end-of-line (BEOL) interconnect layers over such semiconductor portions. Active devices and/or circuitry can be patterned and/or otherwise disposed in or on the device portions 6a, 6b. Active devices and/or circuitry can be disposed at or near the front sides of the device portions 6a, 6b, and/or at or near opposite backsides of the device portions 6a, 6b. The non-conductive material can be referred to as a non-conductive bonding region or bonding layer 5a of the first element 2. In some embodiments, the non-conductive bonding layer 5a of the first element 2 can be directly bonded to the corresponding non-conductive bonding layer 5b of the second element 3 using dielectric-to-dielectric bonding techniques. For example, non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiments, the bonding layers 5a and/or 5b can comprise a non-conductive material such as a dielectric material, such as silicon oxide, or an undoped semiconductor material, such as undoped silicon. Suitable dielectric bonding surface or materials for direct bonding include but are not limited to inorganic dielectric materials including silicon, such as silicon oxide, silicon nitride, fluorinated oxides, fluorinated silicon glass (FSG), or silicon oxynitride, or can include carbon, such as silicon carbide, silicon oxycarbonitride, low K dielectric materials, SiCOH dielectrics, silicon carbonitride, or a diamond-like carbon or a material comprising of a diamond surface. Such carbon-containing ceramic materials can be considered inorganic, despite the inclusion of carbon. In some embodiments, the dielectric materials may not comprise polymer materials, such as epoxy, resin, or molding materials.

In various embodiments, direct hybrid bonds can be formed without an intervening adhesive. For example, non-conductive bonding surfaces 8a, 8b can be polished to a high degree of smoothness. The non-conductive bonding surfaces 8a and 8b can be polished using, for example, chemical mechanical polishing (CMP). The roughness of the polished bonding surfaces 8a and 8b can be less than 30 Å rms. For example, the roughness of the bonding surfaces 8a and 8b can be in a range of about 0.1 Å rms to 15 Å rms, 0.5 Å rms to 10 Å rms, or 1 Å rms to 5 Å rms. The bonding surfaces 8a, 8b can be cleaned and exposed to a plasma and/or etchants to activate the surfaces 8a, 8b. In some embodiments, the surfaces 8a, 8b can be terminated with a species after activation or during activation (e.g., during the plasma and/or etch processes). Without being limited by theory, in some embodiments, the activation process can be performed to break chemical bonds at the bonding surfaces 8a, 8b, and the termination process can provide additional chemical species at the bonding surfaces 8a, 8b that improves the bonding energy during direct bonding. In some embodiments, the activation and termination are provided in the same step, e.g., a plasma to activate and terminate the surfaces 8a, 8b. In other embodiments, the bonding surface 8a, 8b can be terminated in a separate treatment to provide the additional species for direct bonding. In various embodiments, the terminating species can comprise nitrogen. For example, in some embodiments, the terminating species can comprise a nitrogen-bearing fluid or liquid. In some embodiments, the bonding surfaces 8a, 8b can be exposed to a nitrogen-containing plasma. Further, in some embodiments, the bonding surfaces 8a, 8b can be exposed to fluorine. For example, there may be one or multiple fluorine peaks at or near bonding interface 7 between the first and second elements 2, 3. Thus, in the directly bonded structure 1, the bonding interface 7 between two non-conductive materials (e.g., the bonding layers 5a, 5b) can comprise a very smooth interface with higher nitrogen content and/or fluorine peaks at the bonding interface 7. Additional examples of activation and/or termination treatments may be found throughout U.S. Pat. Nos. 9,564,414; 9,391,143; and 10,434,749, the entire contents of each of which are incorporated by reference herein in their entirety and for all purposes. In some embodiments described hereinbelow, a water plasma activation process can leave hydroxyl groups on the planarized surface that is ready for direct bonding, with very low or no nitrogen content at the bonding surface. Furthermore, in some process variants, nitrogen may also be included in the water plasma activation embodiments described below, which may allow stronger bond energy at room temperature, before any anneal.

In various embodiments, conductive features (e.g., conductive contact pads 4a) of the first element 2 can also be directly bonded to corresponding conductive features (e.g., conductive contact pads 4b) of the second element 3. For example, a hybrid bonding technique can be used to provide conductor-to-conductor direct bonds along the bond interface 7 that includes covalently direct bonded non-conductive-to-non-conductive (e.g., dielectric-to-dielectric) surfaces, prepared as described above. In various embodiments, the conductor-to-conductor (e.g., contact pad 4a to contact pad 4b) direct bonds and the dielectric-to-dielectric hybrid bonds can be formed using the direct hybrid bonding techniques disclosed at least in U.S. Pat. Nos. 9,716,033 and 9,852,988, the entire contents of each of which are incorporated by reference herein in their entirety and for all purposes. In direct hybrid bonding embodiments described herein, conductive features are provided within non-conductive bonding layers, and both conductive and non-conductive features are prepared for direct bonding, such as by the planarization, activation and/or termination treatments described above. Thus, the bonding surface prepared for direct hybrid bonding includes both conductive and non-conductive features.

For example, non-conductive (e.g., dielectric) bonding surfaces 8a, 8b (for example, inorganic dielectric surfaces) can be prepared and directly bonded to one another without an intervening adhesive as explained above. Conductive features (e.g., conductive contact pads 4a, 4b, which may be at least partially surrounded by non-conductive dielectric field regions within the bonding layers 5a, 5b) may also directly bond to one another without an intervening adhesive. In various embodiments, the conductive features can comprise discrete pads at least partially embedded in the non-conductive field regions. In some embodiments, the conductive contact features can comprise exposed contact surfaces of traces or through substrate vias (TSVs). In some embodiments, the respective conductive features (e.g., contact pads 4a, 4b) can be recessed below exterior (e.g., upper) surfaces 8a, 8b (e.g., non-conductive bonding surfaces) of the dielectric field region or non-conductive bonding layers 5a, 5b, for example, recessed by less than 30 nm, less than 20 nm, less than 15 nm, or less than 10 nm, for example, recessed in a range of 2 nm to 20 nm, or in a range of 4 nm to 10 nm. However, embodiments of the elements 2, 3 are not limited to those where the conductive features (e.g., contact pads 4a, 4b) are recessed by 30 nm or less. For example, in embodiments where the conductive features have a thickness greater than 5 μm, the conductive features can be recessed by more than 30 nm due to greater vertical expansion of the metal. In various embodiments, prior to direct bonding, the recesses in the opposing elements can be sized such that the total gap between opposing contact pads is less than 30 nm, less than 20 nm, less than 15 nm, or less than 10 nm. For example, in practice, the smaller the total recess, the lower the annealing or bonding temperature. For example, in embodiments where the conductive features have a width of 5-10 μm, the conductive features can be annealed at a temperature below 250° C. The non-conductive bonding layers 5a, 5b can be directly bonded to one another without an adhesive at room temperature in some embodiments and, subsequently, the bonded structure 1 can be annealed. Upon annealing, the conductive features (e.g., contact pads 4a, 4b) can expand and contact one another to form a metal-to-metal direct bond. Beneficially, the use of Direct Bond Interconnect, or DBI®, techniques commercially available from Adeia of San Jose, CA, can enable high density of conductive features (e.g., pads 4a, 4b) to be connected across the direct bond interface 7 (e.g., small or fine pitches for regular arrays). In some embodiments, the pitch p of the conductive features (e.g., bonding pads 4a, 4b or conductive traces embedded in the bonding surface of one of the bonded elements) may be less than 100 microns or less than 10 microns or even less than 2 microns. For some applications, the ratio of the pitch of the conductive features (e.g., bonding pads 4a, 4b) to one of the dimensions (e.g., a diameter) of the bonding pad is less than 20, or less than 10, or less than 5, or less than 3 and sometimes desirably less than 2. In other applications the width of the conductive traces embedded in the bonding surface of one of the bonded elements may range between 0.3 microns to 20 microns, e.g., in a range of 0.3 microns to 3 microns. In various embodiments, the conductive features (e.g., contact pads 4a, 4b and/or traces) can comprise copper, although other metals may be suitable.

Thus, in direct bonding processes, a first element 2 can be directly bonded to a second element 3 without an intervening adhesive. In some arrangements, the first element 2 can comprise a singulated element, such as a singulated integrated device die. In other arrangements, as shown in FIGS. 1A-1B, the first element 2 can comprise a carrier or substrate (e.g., a wafer) that includes a plurality (e.g., tens, hundreds, or more) of device regions that, when singulated, form a plurality of integrated device dies. Similarly, the second element 3 can comprise a singulated element, such as a singulated integrated device die, as shown in FIGS. 1A-1B. In other arrangements, the second element 3 can comprise a carrier or substrate (e.g., a wafer, a flat panel, or a package). The embodiments disclosed herein can accordingly apply to wafer-to-wafer (W2 W), die-to-die (D2D), or die-to-wafer (D2 W) bonding processes. In W2 W processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the singulation process for the bonded structure (e.g., saw markings if a saw singulation process is used).

As explained herein, the first and second elements 2, 3 can be directly bonded to one another without an adhesive, which is different from a deposition process. In one application, a width of the first element 2 in the bonded structure is similar to a width of the second element 3. In some other embodiments, a width of the first element 2 in the bonded structure 1 is different from a width of the second element 3. Similarly, the width or area of the larger element in the bonded structure may be at least 10% larger than the width or area of the smaller element. The first and second elements 2, 3 can accordingly comprise non-deposited elements. Further, directly bonded structures 1, unlike deposited layers, can include a defect region along the bond interface 7 in which nanometer-scale voids (nanovoids) are present. The nanovoids may be formed due to activation of the bonding surfaces 8a, 8b (e.g., exposure to a plasma). As explained above, the bond interface 7 can include concentration of materials from the activation and/or last chemical treatment processes. For example, in embodiments that utilize a nitrogen plasma for activation, a nitrogen peak can be formed at the bond interface 7. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace some of the OH groups of a hydrolized (OH-terminated) surface with N—H moieties or species, yielding a nitrogen-terminated surface. In embodiments that utilize an oxygen plasma and/or water plasma for activation, an oxygen peak can be formed at the bond interface 7. In some embodiments, the bond interface 7 can comprise silicon oxynitride, silicon oxycarbonitride, or silicon carbonitride. As explained herein, the direct bond can comprise a covalent bond, which is stronger than van Der Waals bonds. The bonding layers 5a, 5b can also comprise polished surfaces that are planarized to a high degree of smoothness.

In various embodiments, the metal-to-metal bonds between the contact pads 4a, 4b can be joined such that copper grains grow into each other across the bond interface 7. In some embodiments, the copper grains grow into each other across the bond interface after annealing the bonded structures or substrates, e.g., at temperatures between 50° C. and 400° C. or at temperatures between 80° C. and 300° C. In some embodiments, the copper can have grains oriented along the 111 crystal plane for improved copper diffusion across the bond interface 7. In some embodiments, the conductive features 4a, 4b may have a nanotwinned copper grain structure or may be a fine grain copper having an average grain size (as measured from either the top view or a cross-sectional view) of less than 0.5 μm or even less than 0.3 μm. The bond interface 7 can extend substantially entirely to at least a portion of the bonded conductive features (e.g., bonded contact pads 4a, 4b), such that there is substantially no gap between the non-conductive bonding layers 5a, 5b at or near the bonded conductive features. In some embodiments, a barrier layer may be provided under the conductive features (e.g., which may include copper). In other embodiments, however, there may be no barrier layer under the conductive features, for example, as described in U.S. Pat. No. 11,195,748, which is incorporated by reference herein in its entirety and for all purposes.

Beneficially, the use of the hybrid bonding techniques described herein can enable extremely fine pitch between adjacent contact pads 4a or 4b, and/or small pad sizes. For example, in various embodiments, the pitch p (see FIG. 1A), i.e., the distance from edge-to-edge or center-to-center between adjacent conductive features (e.g., between adjacent contact pads 4a or adjacent contact pads 4b) can be in a range of 0.5 microns to 50 microns, in a range of 0.75 microns to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 microns to 30 microns, in a range of 0.25 microns to 5 microns, or in a range of 0.5 microns to 5 microns.

As described above, the non-conductive bonding layers 8a, 8b can be directly bonded to one another without an adhesive and, subsequently, the bonded structure 1 can be annealed. Upon annealing, the conductive features 4a, 4b can expand and contact one another to form a metal-to-metal direct bond. In some embodiments, the materials of the conductive features 4a, 4b can interdiffuse during the annealing process.

In various embodiments, the second element 3 can comprise a singulated device die, and the first element 2 can comprise a wafer. In other embodiments, both elements 2, 3 can comprise a singulated device die. In such an embodiment, the second element 3 may be initially provided in wafer form or larger substrate and singulated to form the singulated first element 3. However, the singulation process and/or other processing steps may produce debris that can contaminate the planar bonding surface, which can leave voids and/or defects when two elements are bonded. Accordingly, prior to singulation, a protective layer can be provided over the bonding surface before singulation to prevent debris from contaminating the bonding surface. The protective layer can comprise an organic or inorganic layer (e.g., a photoresist) that is deposited (e.g., spin coated onto) the bonding surface. Additional details of the protective layer may be found throughout U.S. Pat. No. 10,714,449, the entire contents of which are incorporated by reference herein in their entirety and for all purposes. The wafer containing the first element can be singulated using any suitable method. The protective layer over the bonding surface can beneficially protect the bonding surface from debris. Before direct bonding, the protective layer can be removed from the bonding surface with a cleaning agent, for example with a suitable solvent, such as an alkaline solution or other suitable cleaning agent as recommended by the supplier of the protective layer. The protective layer cleaning agent can be selected such that it does not substantially roughen the smooth bonding surface of the bonding layer and does not substantially etch or contaminate the metal of the contact pad to increase the recess of the pad metal after subsequent cleaning operations. An excessive pad recess may form a recess that is too deep, which may prevent (or reduce the strength of) pad-to-pad bonding at the appropriate annealing conditions (e.g., annealing temperature and times). The cleaning agent can be applied by a fan spray of the liquid cleaning agent or other known methods. For example, the cleaned bonding surface can be ashed (e.g., using an oxygen plasma) and cleaned with deionized (DI) water. In some embodiments, the cleaned element can be activated before direct bonding. In some embodiments, cleaning and activation can be conducted with the same plasma treatment, such as the water plasma embodiments described hereinbelow.

In some direct bonding systems, the bonding surfaces of the semiconductor elements are terminated by exposing them to nitrogen plasma. The nitrogen plasma interacts with the atoms at the bonding surfaces and provides additional chemical species at the bonding surfaces that improve the bonding energy during direct bonding. However, oxygen plasma tends to interact with the surface of the conductive features, forming metal oxides. For example, where the conductive features comprise aluminum, nickel, or copper conductive features, the oxygen plasma can interact with the surfaces of the conductive features and form aluminum oxide, nickel oxide, or copper oxide, respectively. The presence of aluminum oxide and nickel oxide at the bonding surface of the conductive feature tend to suppress bonding or produce unreliable metallurgical bonding between the opposing conductive pads. Accordingly, these metal oxides are typically removed using various cleaning agents. These cleaning agents can etch the surface of the of the conductive features, which can result in an excessive pad recess and create difficulties in controlling consistent conductor bonding across the substrates. Accordingly, there is a need for a direct bonding process that allows for the activation of bonding surfaces while permitting reliable connections between conductive features in direct hybrid bonding.

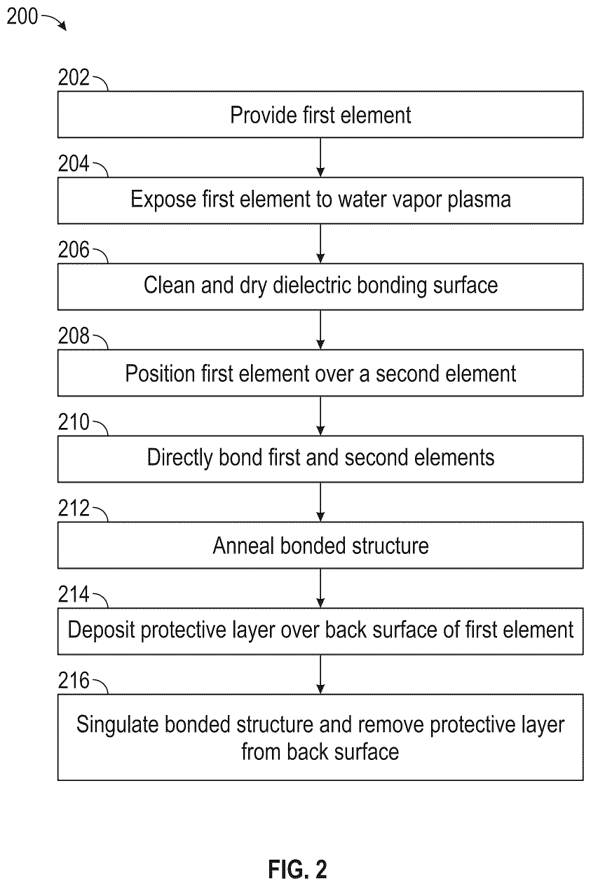

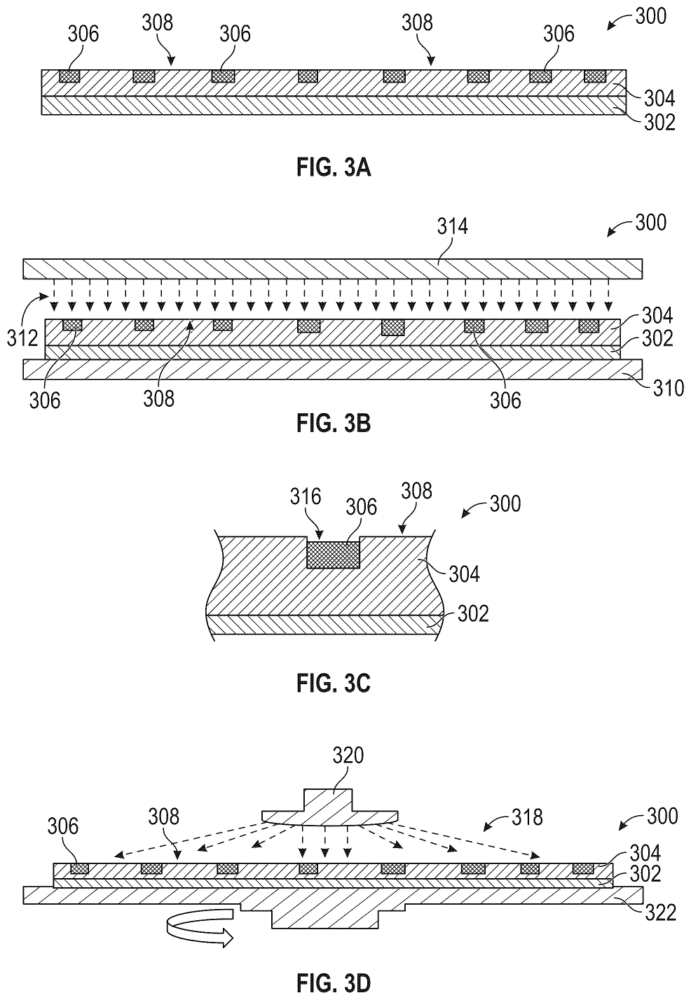

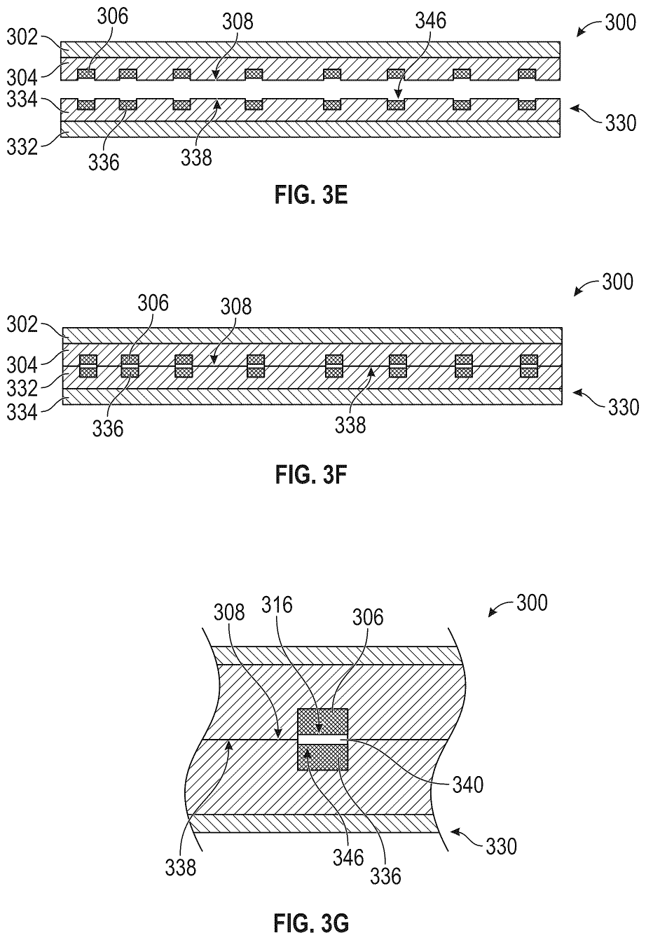

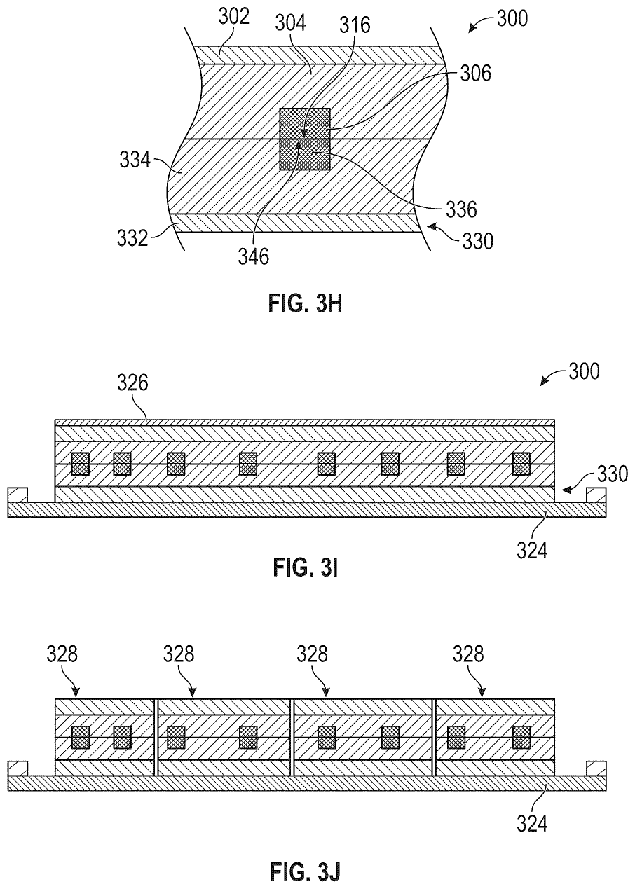

FIG. 2 is a flowchart illustrating a bonding process 200 that includes exposing the bonding surface(s) to water vapor plasma. FIGS. 3A-3J are schematic side sectional views of elements such as semiconductor elements 300, 330 at various blocks of a W2 W example of the process 200 shown in FIG. 2. As shown in FIG. 3A, at block 202, an element to be bonded, such as a semiconductor element 300, is provided. The semiconductor element 300 includes a substrate 302, a dielectric layer 304, and one or more conductive features 306. The dielectric layer 304 has a dielectric bonding surface 308 and the one or more conductive features 306, which can be formed from copper or some other metal, are formed in the dielectric layer 304 such that the conductive features 306 are exposed at the bonding surface 308. The dielectric bonding surface 308 and conductive feature surface 316 may have sufficient planarity such that the surface 308 is suitable for direct bonding.

As shown in FIG. 3B, at block 204, the semiconductor element 300 is exposed to products of a water vapor plasma 312. The water vapor plasma 312 is configured to activate the bonding surfaces of the semiconductor element 300. The semiconductor element 300 is mounted to a carrier 310 and the products of the water vapor plasma 312 are dispersed over the surface 308 of the semiconductor element 300. The skilled artisan will appreciate that in some embodiments, the plasma can be an in situ plasma formed directly over the substrate being treated, in which case a distribution system 314 (e.g., showerhead) supplies water vapor and any other vapors for ignition of plasma within the chamber, e.g., by way of RF power alternating between electrodes such as the carrier 310 and the distribution system 314. In other embodiments, the water vapor plasma is generated remotely from the semiconductor element 300 and products of the water vapor plasma 312 are then supplied to the semiconductor element 300 via the distribution system 314. Many remote plasma generators (RPGs) employ microwave energy coupled to a plasma applicator though which the supplied vapors flow, but the skilled artisan will appreciate that the remote plasma can couple other forms of energy to the water vapor and any other supplied vapors. In some embodiments, the water vapor plasma is formed by exposing water to a strong electromagnetic field, which excites the water and causes it to form a plasma. During the plasma formation process, the water vapor reacts with excited free electrons to form neutral monatomic oxygen, oxygen ions, hydroxy ions, hydrogen ions, and neutral monatomic hydrogen. Two such reactions are shown as Reactions 1 and 2 below:

$${H}_{2} O + {e}^{-} \to H + OH + {e}^{-} \qquad [ 1 ]$$

$${H}_{2} O + {e}^{-} \to O + {H}_{2} + {e}^{-} \qquad [ 2 ]$$

FIG. 3C shows a side schematic view of a portion of the semiconductor element 300 including one of the conductive features 306. The conductive feature 306 has a conductive surface 316 that is recessed below the dielectric bonding surface 308. As noted above, in some embodiments, the conductive surface 316 is recessed below the dielectric bonding surface 308 by less than 20 nm. The smaller the recess the lower the temperature during post-bonding anneal that will cause the conductors from opposite elements to bridge the gap from such recesses. However, because it is difficult to uniformly control the recess depths across the elements, the variation in recess depth for the conductive features 306 across the substrate 302 employed in direct hybrid bonding tends to be between 1 nm and 7 nm or greater, depending on the various processing conditions. Employing water plasma in certain embodiments can facilitate reduced variation of metal recess depth across the substrate 302, such that the variation in metal recess depth may be between 0.2 nm and 2 nm. Employing water plasma in certain embodiments can also facilitate the employment of recesses smaller than 10 nm in depth, such as between 1 nm and 10 nm or between 4 nm and 8 nm. In other embodiments, however, the conductive surface 316 is recessed below the dielectric bonding surface 308 by a different distance. For example, in some embodiments, the conductive surface 316 is recessed below the dielectric bonding surface by 3 nm, 4 nm. 5 nm, 6 nm, 7 nm, 8 nm, or a value in a range defined by any of these values.

When dielectric bonding surfaces are activated by being exposed to an oxygen plasma, the oxygen plasma causes organic material residues at the bonding surfaces to decompose, which can improve bonding performance. However, exposing the dielectric bonding surfaces 308 to an oxygen plasma can oxidize the surface of the conductive features (except for some oxidation-resistant materials such as gold, platinum, iridium, and the like). For example, where the conductive features comprise aluminum, nickel, or copper, ashing the surfaces of the conductive features with an oxygen plasma can result in the formation of a metal oxide layer on the surface of the conductive features. As discussed in greater detail elsewhere in the application, the conductive features can be directly bonded to conductive features on another element. However, some metal oxides, depending on their nature and thickness, can interfere with this direct bonding process and can prevent the direct bond from forming or at least reduce the quality of the bond. For example, while aluminum oxide and nickel oxide will generally be removed before the bonding operation, very thin layers of copper oxide can sometimes be left without removal, because copper oxide tends to be more forgiving than aluminum and nickel oxides, which means that the conductive features will bond more readily. In some cases, the oxygen plasma may activate the dielectric bonding surface. In other cases, however, the nitrogen plasma may activate the dielectric bonding surface to strengthen covalent dielectric bonding at room temperature. In these cases, after exposing the bonding surfaces to the oxygen plasma, the dielectric bonding surfaces may then be exposed to a nitrogen plasma to activate the dielectric surfaces. In some cases, the oxygen plasma may activate the bonding surfaces of the non-conductive features. In practice, after exposing the bonding surface to oxygen plasma, the bonding surface is cleaned with a suitable cleaning agent (for example wet acid solution) and/or by using a suitable cleaning process to remove the oxidized layer from the conductive features of the hybrid bonding surface. However, removing the metal oxide layer from the conductive features using wet cleaning methods typically results in the oxide layer being dissolved by the cleaning agent, thereby increasing the depth of the recess.

Ashed surfaces or activated surfaces of the substrate can be thoroughly rinsed with DI water and thoroughly dried by spin drying or by other known suitable methods. However, such metal oxide removal processes can cause the conductive features to be recessed further. Because some variability in recess depth across the element is introduced by both CMP, which produces the initial recesses, and the subsequent oxidation and oxide removals, the overall recess depths tend to be greater than 8 nm or even greater than 10 nm in order to have the uniformity desired across the element to ensure conductor contacts without local delaminations during hybrid bonding. This larger distance entails higher anneal temperatures to ensure that the conductive features can bond together, which can consume too much thermal budget or cause other thermal problems (e.g., stresses or warping).

In contrast, the water vapor plasma is configured to activate the dielectric bonding surface 308 and to inhibit or prevent formation of copper oxide from the conductive surfaces 316 of the conductive features 306. The products of the water vapor plasma interact with the dielectric bonding surface 308 and breaks chemical bonds at the dielectric bonding surface 308 while simultaneously terminating the dielectric bonding surface 308 with hydroxyl ions, which can aid in the direct bonding process. The water vapor plasma also interacts with the conductive surfaces 316 and reduces the surfaces of the conductive surfaces, thereby inhibiting or preventing oxides from forming on the surfaces 316, or removing any oxides that do form. Advantageously, the water vapor plasma can leave oxide-free conductive surfaces 316 without substantially etching conductive features 306. This means that the wet cleaning methods used to remove metal oxides from the conductive surfaces 316, which typically results in the cleaning agent dissolving the metal oxides and increasing the depth of the recess, can be avoided, along with the additional variability across the substrate that this additional process entails. In this way, exposing the semiconductor element 300 to the water vapor plasma allows for the activation and termination of the bonding surfaces while minimizing the increase in depth that the conductive surface 316 is recessed below the dielectric bonding surface 308. Because one source of recess variability across the substrate is reduced, a smaller recess depth for the conductive surface 316 below the dielectric bonding surface 308 can be targeted, and the post-bonding annealing temperature for joining the conductive features can be reduced.

In some embodiments, exposing the semiconductor element 300 to products of the water vapor plasma includes exposing the semiconductor element 300 to plasma generated from water vapor alone, without supplying another reactant source vapor to the plasma generation apparatus, such as supplying water alone, or water with a noble carrier gas only. In such embodiments, water is the sole reactant supplied to the plasma generation apparatus and to the semiconductor element at block 204.

In other embodiments, however, semiconductor element 300 can be exposed to one or more other reactant source vapors during or prior to the water vapor plasma. Such additional reactant source vapors may be considered inert under some circumstances, such as being supplied to the chamber holding the element to be treated without going through the plasma source apparatus, but are nevertheless considered reactive when supplied through and activated in the plasma source apparatus. For example, in some embodiments, the semiconductor element 300 can be simultaneously exposed to products of a plasma generated by supplying both water vapor and oxygen to the plasma generation apparatus. In some embodiments, a carrier gas can be mixed with the water vapor and supplied to the plasma generation apparatus, exposing the semiconductor element 300 to the products of a plasma formed from both water vapor and the carrier gas. The carrier gas can be configured to help flow the water vapor to the plasma generation device or to supply more mass to help support the plasma generation. While noble gases remain inert or nonreactive even when exposed to plasma, other carrier gases can contribute reactive species to the process. For example, in some embodiments, the carrier gas comprises air. In other embodiments, the carrier gas comprises nitrogen gas, which can activate and contribute some nitrogen termination to the dielectric bonding surface 308 and form stronger covalent bonds at room temperature. In still other embodiments, the carrier gas comprises hydrogen gas, which can boost the oxide prevention or reduction of hydrogen species supplied by the water plasma. The addition of a very small amount fluorine species (e.g., less than 10% of the fluid supplied to the plasma by volume or flow rate, less than 5% or even less than 1%) to the plasma can also provide activation and terminations to strengthen direct dielectric bonding at room temperature. One of the advantages of water plasma treatment of the bonding surface is that it can facilitate in situ activation and termination of the non-conductive bonding surface while reducing or preventing oxide layer formation on the exposed conductive features.

As shown in FIG. 3D, at block 206, after exposing the semiconductor element 300 to the products of the water vapor plasma, the semiconductor element 300 can be cleaned and dried. In some embodiments, the semiconductor element 300 can be cleaned by rinsing the dielectric bonding surface 308 with DI water 318. The DI water 318 can remove unwanted debris the dielectric bonding surface, such as spurious particles from the plasma chamber or sputtered from the dielectric bonding surface and deposited on the dielectric bonding surface. After cleaning the dielectric bonding surface 308, the semiconductor element 300 can be dried. In some embodiments, drying can comprise spin drying. In these embodiments, the semiconductor element 300 can be mounted to a spin-drying apparatus 322 and the semiconductor element 300 can be spin-dried for between 30 seconds and 240 seconds at a rate of 1000 RPM to 4000 RPM. In some embodiment, the cleaning and rinsing step may comprise low molecular weight organic solvents, such as methyl alcohol, isopropanol, or butyl alcohol, and the drying step can be performed according to other know methods, such as Marangoni drying.

As shown in FIG. 3E, at block 208, the semiconductor element 300 is positioned over a second element, such as the illustrated semiconductor element 330. The second semiconductor element 330 includes a second substrate 332, a second dielectric layer 334, and one or more second conductive features 336. The second dielectric layer 334 has a second dielectric bonding surface 338 and the one or more second conductive features 336, which can be formed from copper or some other metal, are formed in the second dielectric layer 334 such that the second conductive features 336 are exposed at the second bonding surface 338. In some embodiments, the second conductive features 336 have second conductive surfaces 346 that are recessed below the second dielectric bonding surface 338. The second dielectric bonding surface 338 may have sufficient planarity such that the second dielectric bonding surface 338 is suitable for direct bonding. In some embodiments, the semiconductor element 300 is positioned over the second semiconductor element 330 such that the dielectric bonding surface 308 faces the second dielectric bonding surface 338 and such that conductive portions 306 of the semiconductor element 300 are aligned with and directly over second conductive portions 336 of the second semiconductor element 330 and non-conductive portions of the semiconductor element 300 are aligned with and directly over non-conductive portions of the second semiconductor element 330. Specifically, the semiconductor element 300 is positioned over the second semiconductor element 330 such that each of the conductive features 306 is aligned with and directly over one of the second conductive features 336 and non-conductive portions of the dielectric layer 304 are positioned over and aligned with non-conductive portions of the second dielectric layer 334.

In some embodiments, before the semiconductor element 300 is positioned over the second semiconductor element 330, the second semiconductor element 330 is prepared for direct bonding. In some embodiments, preparing the second semiconductor element 330 for direct bonding includes exposing the second dielectric bonding surface 338 to products of a water vapor plasma, cleaning the second semiconductor element 330 by rinsing the second dielectric bonding surface 338 with DI water, and then drying the second semiconductor element 330. In other embodiments, however, the semiconductor element 300 is prepared for bonding using a different process. As is known in the art, both elements in a direct hybrid bonding process may be provided with a suitably planar surface and recessed conductors, but one or both of the elements may be exposed to activation and/or termination processes prior to bonding. In some embodiments, the substrate 300 comprises one or more through-substrate electrodes having exposed conductive surfaces on the backside of the substrate 300. In these embodiments, an additional substrate (not shown) having a prepared bonding surface with conductive features may be directly bonded on the backside of substrate 300 before the higher temperature annealing step. The conductive features on the additional substrate can be directly bonded to the one or more through-substrate electrodes on the backside of the substrate 300.

As shown in FIG. 3F, at block 210, the semiconductor elements 300, 330 are directly bonded to each other. In some embodiments, directly bonding the semiconductor elements 300, 330 together includes directly bonding the dielectric bonding surfaces 308, 338 together without an intervening adhesive, as explained above in connection with FIGS. 1A and 1B. In some embodiments, the dielectric bonding surfaces 308, 338 can be directly bonded together using dielectric-to-dielectric bonding techniques. Hydroxyl terminations supplied by exposure to the products of the water vapor plasma at block 204 permit strong bonds at room temperature and without external pressure, sufficient to withstand additional movement of the bonded structure, for example to an anneal station, whether or not additional terminating species are provided. In some embodiments, elevated temperature and/or external pressure can be employed during the initial dielectric bonding. Additional terminating species, such as nitrogen or fluorine, can provide even stronger covalent bonding at room temperature and obviate elevated temperature and external pressure. The dielectric bonding may form covalent bonds even at room temperature.

As discussed elsewhere in the application, the conductive surfaces 316, 346 of the conductive features 306, 336 are recessed below the respective dielectric bonding surfaces 308, 338. Accordingly, as shown in FIG. 3G, after directly bonding the dielectric bonding surfaces 308, 338 together, the recessed conductive features 306, 336 are separated from each other by a gap 340. In some embodiments, the conductive features 306, 336 are recessed such that the distance between the conductive surfaces 316, 346 is less than 40 nm, less than 30 nm, less than 20 nm, or less than 16 nm, such as 12 nm. For example, in some embodiments, the distance between the conductive surfaces 316, 346 after directly bonding the dielectric bonding surfaces 308, 338 is 6 nm, 8 nm, 10 nm, 12 nm, 14 nm, or a value in a range defined by any of these values.

At block 212, the bonded structure is annealed. Upon annealing, the conductive features 306, 336 expand into the gap 340 and contact one another to form a metal-to-metal direct bond. As shown in FIG. 3H, after annealing the conductive features 306, 336 are in direct contact with each other. For a gap 340 size up to 30 nm, an anneal temperature of 250° C. or less can cause the conductive features to expand enough to contact the opposing conductive feature and ensure good electrical connections. Similarly, for a gap 340 size between 12 nm and 15 nm, or a gap 340 size between 15 nm and 20 nm, an anneal temperature between 200° C. and 250° C. can cause the conductive features to expand enough to contact the opposing the conductive feature and ensure good electrical connections. Because embodiments described herein can allow for smaller gaps, the bonded structure can be annealed at lower temperatures. For example, in embodiments where the distance between the conductive surfaces 316, 346 is 12 nm or less, the bonded structure can be annealed at a temperature between 130° C. and 200° C. Further, in embodiments where the distance between the conductive surfaces 316, 346 is 6 nm, the bonded structure can be annealed at a temperature between 160° C. and 180° C. In general, the bonded structure can be annealed at a temperature of 160° C. 170° C. 180° C., 190° C., 200° C., or a value in a range defined by any of these values. Advantageously, annealing the bonded structure at a lower temperature reduces consumption of thermal budgets and thermal stresses.

In some embodiments, after directly bonding the semiconductor elements 300, 330 and then annealing the bonded structure, the bonded structure can be processed further before being singulated into a plurality of semiconductor dies. In some embodiments, this further processing may comprise thinning the backside of the substrate 300 and/or the substrate 330. The further processing can also comprise polishing the backside of substrate 300 and/or substrate 330. In some embodiments, an embedded through electrode (e.g., a TSV) formed in one or both of the substrates 300, 330 may be revealed by known methods, thereby exposing the planar or non-planar conductive features on the backside of the substrate 300 and/or the substrate 330. As shown in FIG. 3I, at block 214, the bonded structure is mounted onto a dicing frame 324 and a protective layer 326 is deposited on a back surface of the semiconductor element 300. The protective layer 326 can be configured to protect the back surface of the semiconductor element 300 from debris from the singulation process, which could interfere with subsequent bonding processes.

As shown in FIG. 3J, at block 216, the bonded structure is singulated into a plurality of dies 328 and the protective layer 326 is removed. The bonded structure can be singulated using any suitable method and the protective layer 326 can be removed using any suitable means.

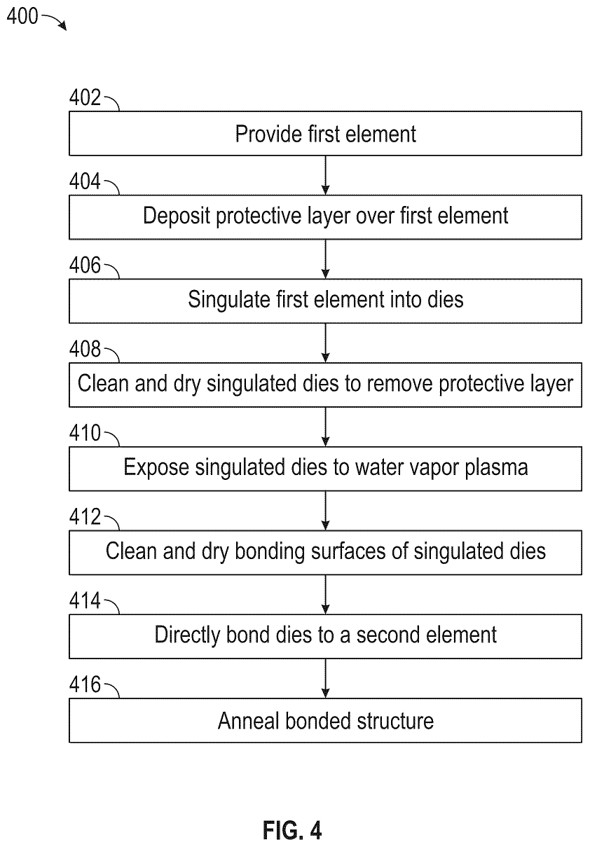

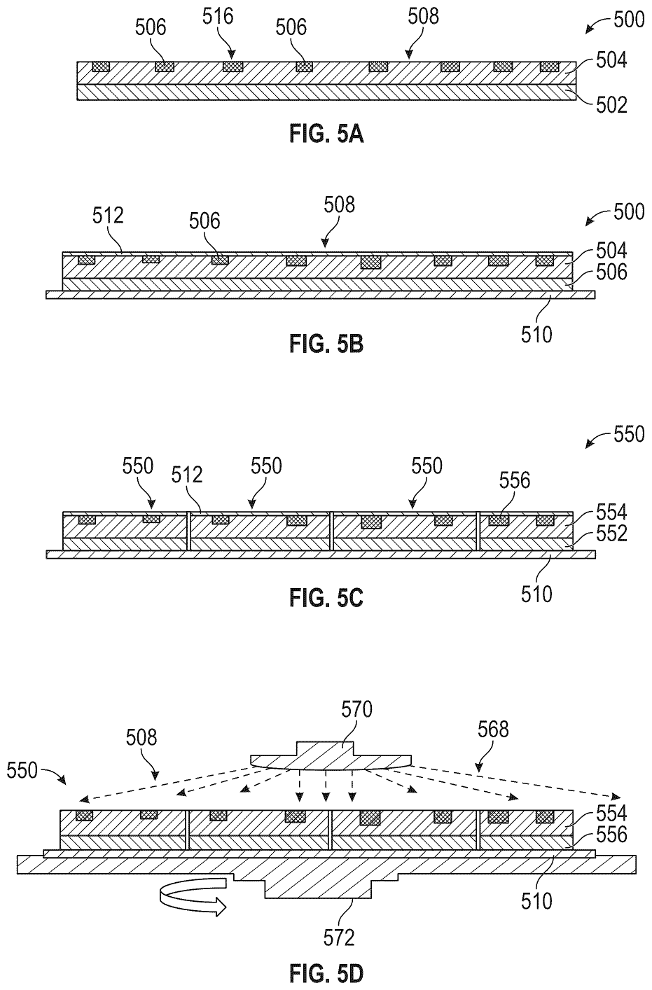

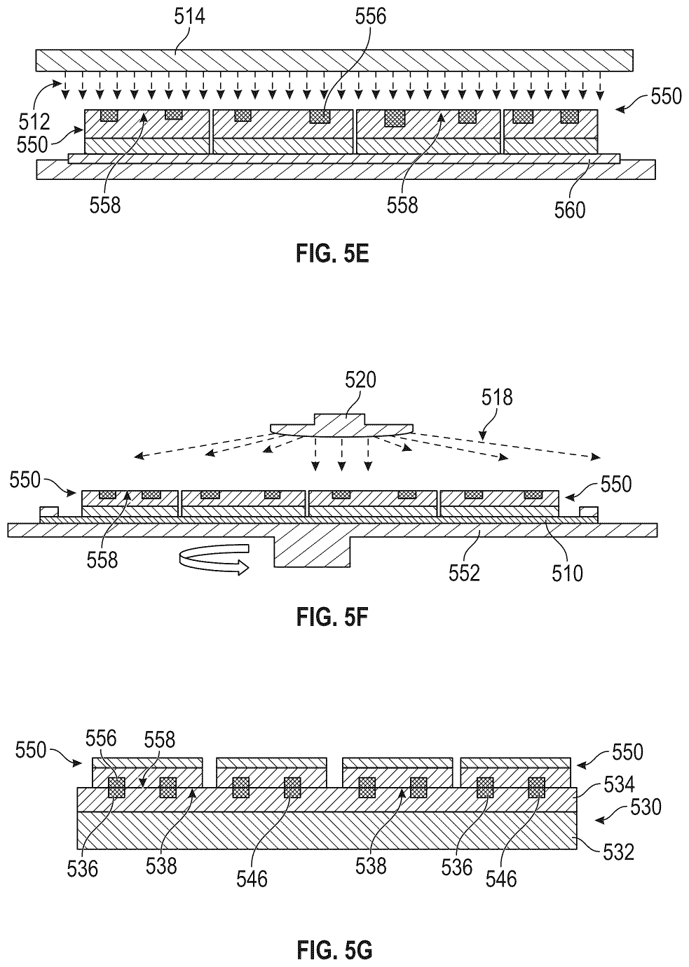

FIG. 4 is a flowchart illustrating a D2 W bonding process 400 that includes exposing the bonding surface(s) of the dies to water vapor plasma. The skilled artisan will appreciate that the illustrated process 400 can be applied to singulating and bonding devices to other substrates regardless of whether the other substrates are in the shape of wafers, such as D2D processes. FIGS. 5A-5G are schematic side sectional views of semiconductor elements 500, 530 at various blocks of the D2 W process 400 shown in FIG. 4. Unless otherwise noted, features or blocks of FIGS. 4 and 5A-5H may be the same as or generally similar to features or blocks of FIGS. 2 and 3A-3J.

As shown in FIG. 5A, at block 402, an element to be singulated into multiple elements and then bonded, such as a semiconductor element 500, is provided. The semiconductor element 500 includes a substrate 502, a dielectric layer 504, and one or more conductive features 506. The skilled artisan will appreciate that, for integrated circuits, the substrate 502 may include bulk or single crystal semiconductor materials as well as other device layers and BEOL interconnect layers. The dielectric layer 504 has a dielectric bonding surface 508 and the one or more conductive features 506, which can be formed from copper or some other metal, are formed in the dielectric layer 504 such that the conductive features 506 are exposed at the bonding surface 508. The dielectric bonding surface 508 may have sufficient planarity such that the surface 508 is suitable for direct bonding, as described above. The conductive features 506 have a conductive surface 516 that, in some embodiments, is recessed below the dielectric bonding surface 508.

As shown in FIG. 5B, at block 404, the semiconductor element 500 is mounted onto a dicing frame 510 and a protective layer 512 is deposited on the dielectric bonding surface 508. The protective layer can comprise an organic or inorganic layer and can be configured to protect debris from contaminating the dielectric bonding surface 508 during singulation. In one embodiment, the protective layer 512 comprises an organic material, such as photoresist. In some embodiments, the protective layer may be coated over the bonding surface 508 of the semiconductor element 500, before being mounted on the dicing sheet 510.

As shown in FIG. 5C, at block 406, the semiconductor element 500 in wafer or other large format is singulated into a plurality of semiconductor elements 550 in singulated die form. The semiconductor element 500 can be singulated using any suitable method, including but not limited to sawing, reactive ion etching (RIE), wet etch, molecular ion beam, laser singulation, or a combination thereof. Each of the singulated semiconductor elements 550 include a substrate 552, a dielectric layer 554, and one or more conductive features 556.

As shown in FIG. 5D, at block 408, the semiconductor elements 550 are cleaned and dried to remove the protective layer 512 from the dielectric bonding surfaces 558 of the semiconductor elements 550. For example, semiconductor elements 550 can be cleaned using a cleaning agent 568 that is applied to the dielectric bonding surfaces 558 with a liquid dispersion device 570. For removing an organic (e.g., photoresist) protective layer 512, the cleaning agent 568 can comprise a suitable solvent, such as an alkaline solution or other suitable cleaning agent as recommended by the supplier of the protective layer. After removing the protective layer 512 from the dielectric bonding surfaces, the singulated semiconductor elements 550 can be rinsed and dried. In some embodiments, drying can comprise spin drying. In these embodiments, the semiconductor elements 550 can be mounted with the dicing frame 510 or other carrier to a spin-drying apparatus 572 and the semiconductor elements 550 can be spin-dried for between 30 seconds and 240 seconds at a rate of 1000 RPM to 4000 RPM.

As shown in FIG. 5E, at block 410, in some embodiments, the semiconductor elements 550 are exposed to products of a water vapor plasma 512. The semiconductor elements 550 are mounted to a carrier 560 and products of the water vapor plasma 512 are dispersed over the surface 558 of the semiconductor element 550. As noted above, in situ or remote plasma systems can be employed, such that the distribution system 514 (e.g., showerhead) can either supply vapors for plasma ignition in the same chamber that holds the semiconductor elements 550, or products of a remotely generated plasma are fed through the distribution system 514. As described above in connection with FIGS. 2 and 3B, the products of the water vapor plasma can comprise reactive species of oxygen and hydrogen, such as oxygen ions, monatomic neutral oxygen, hydroxy ions, hydrogen ions, and monatomic neutral hydrogen, and is configured to activate the dielectric bonding layer and terminate it with additional chemical species. The water vapor plasma is also configured to clean the surfaces of the conductive features 556 to inhibit or remove any oxides that form. As noted above, in some embodiments water is the only reactant supplied to the plasma; in some embodiments reactive additives can include hydrogen- or nitrogen-containing vapors supplied through the plasma generation apparatus.

As noted with respect to block 204, exposure of the singulated semiconductor elements 550 at block 408 to products of the water vapor plasma can similarly activate the dielectric bonding surface 508, terminate with hydroxyl groups and possibly other terminating species if supplied to the plasma, and inhibit, prevent, or remove any oxide formed on the conductive surfaces 516, permitting smaller recesses as described above. Additionally, the products of the water vapor plasma can also clean any remaining organic residue left after removal of the protective layer 512. Advantageously, this function of the water vapor plasma can obviate separate ashing steps with oxygen plasma for cleaning organic residue, and thus minimize consumption of conductive surfaces 516 due to oxidation during such ashing steps.

As shown in FIG. 5F, at block 412, after exposing the semiconductor elements 550 to products of the water vapor plasma, the semiconductor elements 550 are cleaned and dried. In some embodiments, the semiconductor elements 550 can be cleaned by rinsing the dielectric bonding surfaces 558 with DI water 518. The DI water 518 is configured to remove unwanted debris from the dielectric bonding surface. In some embodiments, the DI water 518 is dispersed over the dielectric bonding surfaces 558 with a liquid dispersion device 520. After cleaning the dielectric bonding surfaces 558, the semiconductor element can be dried. In some embodiments, drying can comprise spin drying. In these embodiments, the semiconductor elements 550 can be mounted to a spin-drying apparatus 522 and the semiconductor elements 550 can be spin-dried for between 30 seconds and 240 seconds at a rate of 1000 RPM to 4000 RPM. In some embodiments, after the simultaneous activation and termination of the dielectric bonding surface 558 and reduction of any oxide on the conductive features 556, the treated surfaces of the semiconductor elements 550 can be rinsed (e.g., with a low molecular weight alcohol) before the drying step. In some embodiments, the treated surface of the semiconductor elements 550, as well as the dicing frame 510 may be cleaned with an alkaline liquid and rinsed with DI water or another suitable fluid before drying. The cleaning liquid can be selected such that it cleans the bonding surface of the semiconductor elements 550 without contaminating the dielectric bonding surface 558 or significantly degrade the surface of the conductive feature 556.

As shown in FIG. 5G, at block 414, after exposure to the products of the water vapor plasma, one or more of the semiconductor elements 550 are directly bonded to the prepared surface of a second element, such as a second semiconductor element 530. The second semiconductor element 530 includes a substrate 532, a dielectric layer 534, and one or more conductive features 536. The skilled artisan will appreciate that, for integrated circuits, the substrate 532 may include bulk or single crystal semiconductor materials as well as other device layers and BEOL interconnect layers. The dielectric layer 534 has a dielectric bonding surface 538 and the one or more conductive features 536, which can be formed from copper or some other metal, are formed in the dielectric layer 534 such that the conductive features 536 are exposed at the bonding surface 538. The conductive features 536 have conductive surfaces 546 that are recessed below the dielectric bonding surface 538 and the dielectric bonding surface 538 has sufficient planarity such that the surface 538 is suitable for direct bonding. In some embodiments, the semiconductor elements 550 are positioned over the second semiconductor element 530 such that the conductive features 556 are aligned with and directly over corresponding the conductive features 536 and non-conductive portions of the dielectric layer 554 are positioned over and aligned with non-conductive portions of the dielectric layer 534.

In some embodiments, before the semiconductor elements 550 are positioned over the second semiconductor element 530, the second semiconductor element 530 is prepared for direct bonding. In some embodiments, preparing the second semiconductor element 530 for direct bonding includes exposing the dielectric bonding surface 538 to water vapor plasma, cleaning the second semiconductor element 530 by rinsing the dielectric bonding surface 538 with DI water or by other suitable cleaning methods, and then drying the second semiconductor element 530. In other embodiments, however, the second semiconductor element 530 is prepared for bonding without separate activation and/or termination, or using different activation and/or termination processes.

After positioning the semiconductor elements 550 over the second semiconductor element 530, the semiconductor elements 550, 530 are directly bonded to each other by directly bonding the dielectric bonding surfaces 558, 538 together without an intervening adhesive, as explained above in connection with FIGS. 1A and 1B. In some embodiments, the dielectric bonding surfaces 558, 538 can be directly bonded together using dielectric-to-dielectric bonding techniques. Hydroxyl terminations supplied by exposure to the products of the water vapor plasma at block 410 permit strong bonds at room temperature and without external pressure, sufficient to withstand additional movement of the bonded structure, for example to an anneal station, whether or not additional terminating species are provided. In some embodiments, elevated temperature and/or external pressure can be employed during the initial dielectric bonding. Additional terminating species, such as nitrogen or fluorine, can provide even stronger covalent bonding between the dielectric bonding surfaces 558, 538 at room temperature.

At block 416, the bonded structure is annealed. As described above in connection with FIGS. 2, 3G, and 3H, the conductive features 536, 556 can be recessed below their respective dielectric bonding surfaces 538, 558 such that, after directly bonding the semiconductor elements 550 to the second semiconductor element 530, the conductive features 536, 556 are separated from each other by a gap. Annealing the bonded structure causes the conductive features 536, 556 to expand and contact one another to form a metal-to-metal direct bond. In some embodiments, due to smaller recesses and consequently smaller gaps in the bonded structure, the bonded structure can be annealed at lower temperature than with larger gaps, such as a temperature of 160° C., 170° C., 180° C., 190° C., 200° C., or a value in a range defined by any of these values or specified annealing conditions.

In some embodiments, after annealing the bonded structure, the bonded structure can be singulated using any suitable method, including, but not limited to, sawing, RIE, wet etching, molecular ion beam, leaser singulation, or a combination thereof. The singulated bonded structure can comprise one or more semiconductor elements 550 directly bonded to a singulated portion of the second semiconductor element 530. In some embodiments, the semiconductor element(s) 550 bonded to the singulated portion of the second semiconductor element 530 can be smaller than the singulated portion of the second semiconductor element 530. In some embodiments, multiple semiconductor elements 550 can be bonded to the singulated portion of the second semiconductor element 530. For example, in some embodiments, multiple semiconductor elements 550 are directly bonded to the prepared surface (including portions of the dielectric bonding surface 538) of singulated portion of the second semiconductor element 530. In some embodiments, after annealing the bonded structure, some or all of the bonded structure can be encapsulated in a polymeric layer prior to the bonded structure being singulated. In some embodiments, the singulated bonded structure can be encapsulated with a molding layer.

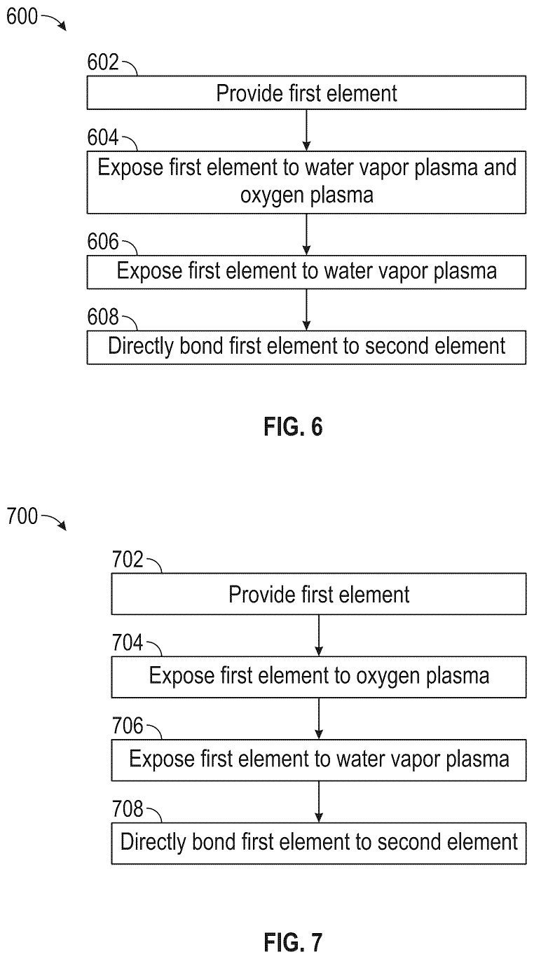

In the embodiments described above in connection with FIGS. 2-5G, the dielectric bonding surfaces are exposed to water vapor plasma without being exposed to any other plasma. In other embodiments, however, the dielectric bonding surfaces can also be exposed to oxygen plasma. FIGS. 6 and 7 are flowcharts illustrating alternative bonding processes that include exposing semiconductor elements to both water vapor plasma and oxygen plasma. Unless otherwise noted, features or steps of FIGS. 6 and 7 may be the same as or generally similar to features or steps of FIGS. 2-5G.

FIG. 6 is a flowchart illustrating a bonding process 600 that includes initially exposing a bonding surface to both water vapor plasma and oxygen plasma and then exposing the bonding surface to just water vapor plasma. At step 602, an element such as a semiconductor element is provided. The semiconductor element includes a substrate (which as noted above can include bulk or single crystal semiconductor material and BEOL layers), a dielectric layer having a dielectric bonding surface, and one or more conductive features formed in the dielectric layer such that the conductive features are exposed at the bonding surface. In some embodiments, the semiconductor element is provided in wafer form. In other embodiments, the semiconductor element is provided in singulated die form. In some embodiments, the element comprises a substrate or package having planar redistribution layer (RDL) that forms a bonding surface for the element. In some embodiments, the substrate or package may comprise a partially- or fully-embedded die or device beneath the bonding surface of the substrate or package.

At block 604, the dielectric bonding surface is exposed to products of a water vapor and oxygen plasma. The products of the oxygen and water vapor plasma are configured to activate the dielectric bonding surface. The products of water vapor plasma are also configured to clean the exposed surfaces of the conductive features so as to inhibit, prevent, or remove any oxides that may form on the conductive surfaces. In some embodiments, the dielectric bonding surface is also exposed to a carrier gas. In some embodiments, after exposing the dielectric bonding surface to the products of oxygen and water vapor plasma, the dielectric bonding surface can be rinsed with DI water and then dried.

At block 606, the dielectric bonding surface is exposed to products of a water vapor plasma. As described elsewhere in the application, the products of the water vapor plasma are configured to clean the surfaces of the conductive features and also to terminate the dielectric bonding surface with hydroxyl groups to improve the bonding energy during direct bonding. In some embodiments, the dielectric bonding surface is also exposed to a carrier gas, which can include other reactive (e.g., terminating) species as disclosed above. Block 606 may directly follow block 604 without intervening treatments. In some embodiments, after exposing the dielectric bonding surface to products of the water vapor plasma, the dielectric bonding surface can be rinsed with DI water and then dried.

At block 608 the first semiconductor element is directly bonded to a second semiconductor element. In some embodiments the first and second semiconductor elements are directly bonded together without an intervening adhesive. In some embodiments, directly bonding the first and second semiconductor elements comprises annealing the bonded structure to form a metal-to-metal direct bond between the conductive features on the first semiconductor element and conductive features on the second semiconductor element. In some embodiments, before directly bonding the first and second semiconductor elements, the second semiconductor element is prepared for direct bonding, where preparing the second semiconductor element for direct bonding includes exposing the dielectric bonding surface to water vapor plasma. In other embodiments, the second semiconductor element is prepared for direct bonding using a different process. Hydroxyl terminations supplied by exposure to the products of the water vapor plasma at block 606 permit strong bonds at room temperature and without external pressure, sufficient to withstand additional movement of the bonded structure, for example to an anneal station, whether or not additional terminating species are provided. In some embodiments, elevated temperature and/or external pressure can be employed during the initial dielectric bonding. Additional terminating species, such as nitrogen or fluorine, can provide even stronger covalent bonding between the dielectric bonding surfaces at room temperature.

FIG. 7 is a flowchart illustrating a bonding process 700 that includes initially exposing a bonding surface to oxygen plasma and then exposing the bonding surfaces to water vapor plasma. At block 702, an element such as a semiconductor element is provided. The semiconductor element includes a substrate (which as noted above can include bulk or single crystal semiconductor material and BEOL layers), a dielectric layer having a dielectric bonding surface, and one or more conductive features formed in the dielectric layer such that the conductive features are exposed at the bonding surface. In some embodiments, the semiconductor element is provided in wafer form. In other embodiments, the semiconductor element is provided in singulated die form. In some embodiments, the element comprises a substrate or package having a planar RDL that forms a bonding surface for the element. In some embodiments, the substrate or package comprises a partially embedded or fully embedded die or device beneath the bonding surface of the substrate or package.

At block 704, the dielectric bonding surface is exposed to products of an oxygen plasma. The products of the oxygen plasma are configured to activate the dielectric bonding surface.

At block 706, the dielectric bonding surface is exposed to products of a water vapor plasma. As described elsewhere in the application, the products of the water vapor plasma are configured to clean the surfaces of the conductive features and also to terminate the dielectric bonding surface with hydroxyl groups to improve the bonding energy during direct bonding. In some embodiments, the dielectric bonding surface is also exposed to a carrier gas, which can include other reactive (e.g., terminating) species as disclosed above. Block 706 may directly follow block 704 without intervening treatments. In some embodiments, after exposing the dielectric bonding surface to water vapor plasma, the dielectric bonding surface can be rinsed with DI water or other suitable solvent or fluid and then dried.

At block 708 the first semiconductor element is directly bonded to a second semiconductor element. In some embodiments the first and second semiconductor elements are directly bonded together without an intervening adhesive. In some embodiments, directly bonding the first and second semiconductor elements comprises annealing the bonded structure to form a metal-to-metal direct bond between the conductive features on the first semiconductor element and conductive features on the second semiconductor element. In some embodiments, before directly bonding the first and second semiconductor elements, the second semiconductor element is prepared for direct bonding, where preparing the second semiconductor element for direct bonding includes exposing the dielectric bonding surface to water vapor plasma. In other embodiments, the second semiconductor element is prepared for direct bonding using a different process. Hydroxyl terminations supplied by exposure to the products of the water vapor plasma at block 706 permit strong bonds at room temperature and without external pressure, sufficient to withstand additional movement of the bonded structure, for example to an anneal station, whether or not additional terminating species are provided. In some embodiments, elevated temperature and/or external pressure can be employed during the initial dielectric bonding. Additional terminating species, such as nitrogen or fluorine, can provide even stronger covalent bonding between the dielectric bonding surfaces at room temperature.

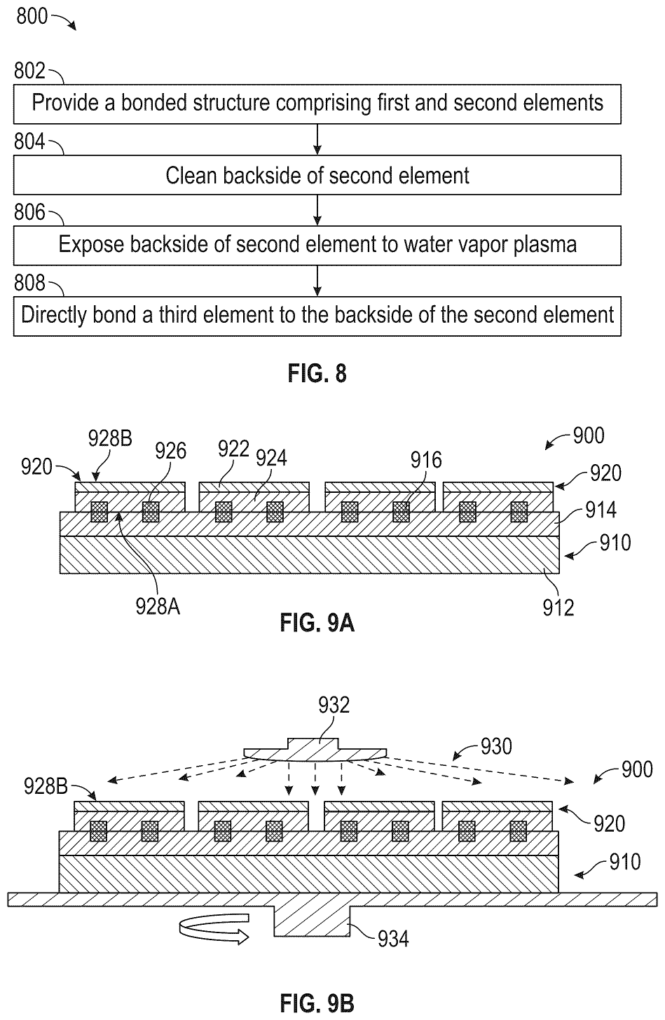

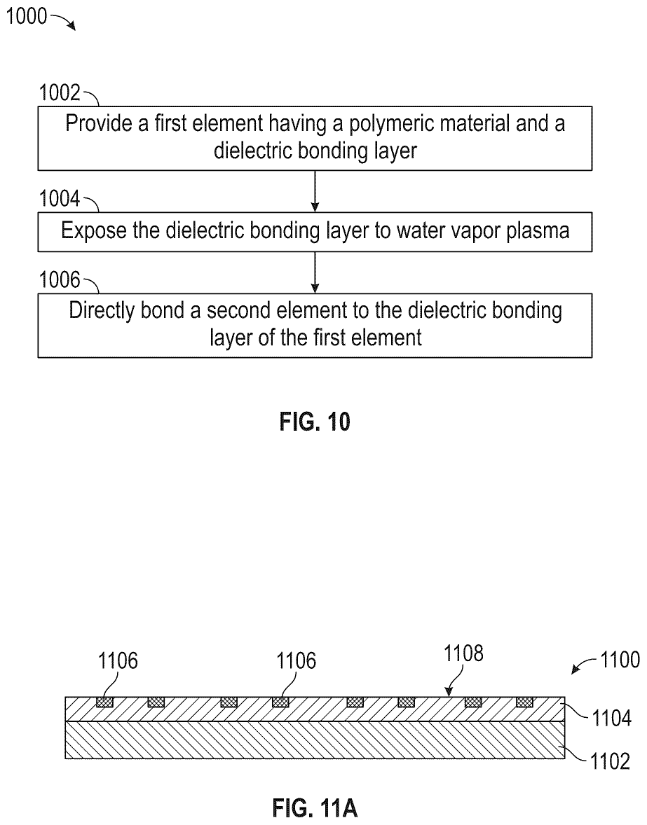

In the embodiments described above in connection with FIGS. 2-7, the products of the water vapor plasma can activate and terminate the dielectric bonding surfaces, such as front sides, of microelectronic elements to prepare the semiconductor elements for direct hybrid bonding. In other embodiments, other surfaces of the elements to be bonded can be exposed to the water vapor plasma. FIGS. 8 and 10 are flowcharts illustrating alternative bonding processes that include exposing other surfaces of elements to the products of a water vapor plasma.

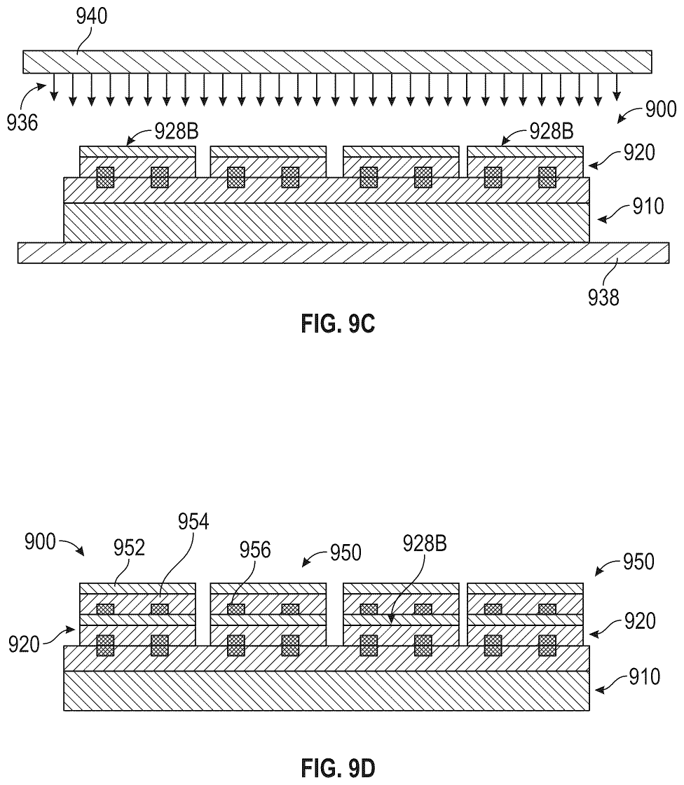

FIG. 8 is a flowchart illustrating an alternative bonding process 800 that includes exposing a backside of a semiconductor element in a bonded structure to the products of a water vapor plasma. FIGS. 9A-9D are schematic side sectional views of a bonded structure 900 at various blocks of the bonding process 800 shown in FIG. 8. Unless otherwise noted, features or blocks of FIGS. 8 and 9A-9D may be the same as or generally similar to features or blocks of FIGS. 2-7.

As shown in FIG. 9A, at block 802, a bonded structure 900 is provided. The bonded structure 900 includes a first element, such as a first semiconductor element 910, and a plurality of second elements, such as a plurality of second semiconductor elements 920, directly bonded to the first semiconductor element 910. In the illustrated embodiment, the first semiconductor element 910 is provided in wafer form while the second semiconductor elements 920 are provided in singulated die form. In other embodiments, however, the second semiconductor elements 920 can also be provided in wafer form. In such embodiments, only a single semiconductor element 920 may be directly bonded to the first semiconductor element 910.

The semiconductor element 910 includes a substrate 912 (which as noted above can include a bulk or single crystal semiconductor material and may also have one or more BEOL layers; other elements can include a package with partially or fully embedded dies, or a temporary substrate having a bonding surface comprising an RDL layer with conductive features), a dielectric layer 914, and one or more conductive features 916 formed in the dielectric layer 914. Similarly, the semiconductor elements 920 each include a substrate 922 (which can similarly include bulk or single crystal semiconductor material and can also have one or more BEOL layers; other elements can include a singulated package, or a substrate having a bonding surface comprising an RDL layer with conductive features), a dielectric layer 924, and one or more conductive features 926 formed in the dielectric layer 924. The second semiconductor elements 920 each have a frontside 928A and a backside 928B having a bonding surface comprising one or more conductive features adapted for hybrid bonding. The frontside 928A includes the dielectric layer 924 and the conductive features 926 and the backside 928B is defined by the substrate 922 or any additional backside layers (e.g., bonding layer(s)). The semiconductor element 910 and the second semiconductor elements 920 can be directly bonded together such that the dielectric layers 914, 924 are directly bonded to each other without an intervening adhesive and the conductive features 916, 926 are directly bonded to each other and form a metal-to-metal direct bond. With this arrangement, the frontsides 928A of the second semiconductor elements 920 faces and directly contacts the semiconductor element 910 while the backsides 928B face away from the semiconductor element 910. The bonded structure 900 can be formed, for example, by the process of FIG. 4. In some embodiments, before subsequent processing, the bonded structure 900 can be annealed or exposed to a heat source to enhance the bond strength of the bonded structure 900.

As shown in FIG. 9B, at block 804, the backsides 928B of the second semiconductor elements 920 are cleaned. The backsides 928B are cleaned using a cleaning agent 930 that is applied to the backsides 928B with a liquid dispersion device 932. In some embodiments, the cleaning agent 930 comprises a suitable solvent, such as an alkaline solution or other suitable cleaning agent. The cleaning agent 930 is configured to remove contaminants on the backsides 928B of the semiconductor element 920. In some embodiments, the cleaning agent comprises DI water. After cleaning the backsides 928B, the bonded structure can be dried. In some embodiments, drying can comprise spin drying or other known drying methods. In these embodiments, the bonded structure 900 can be mounted to a spin-drying apparatus 934 and the bonded structure 900 can be spin-dried for between 30 seconds and 240 seconds at a rate of 1000 RPM to 4000 RPM.

As shown in FIG. 9C, at block 806, the backsides 928B of the second semiconductor elements 920 are exposed to products of a water vapor plasma 936. The bonded structure 900 is mounted to a carrier 938 and the products of the water vapor plasma 936 are dispersed over the backsides 928B to treat the backside bonding surface. In some embodiments, a distribution system 940 is used to disperse products of water vapor plasma over the backsides 928B. As described in greater detail elsewhere in the specification, the products of water vapor plasma 936 can comprise reactive species of oxygen and hydrogen, such as oxygen ions, atomic oxygen, hydroxy ions, hydrogen ions, and atomic hydrogen and are configured to activate the backsides 928B of the semiconductor elements 920 and to terminate it with additional chemical species to improve the bonding energy during direct bonding. In some embodiments, the backsides 928B are also exposed to plasma products of a carrier gas, which can include additional terminating species such as nitrogen or fluorine. In some embodiments, after exposing the backsides 928B to the water vapor plasma, the backsides are cleaned with DI water and then dried. In some embodiments, the backsides 928B have only semiconductor or inorganic dielectric surfaces that can be terminated with hydroxyl and possible other terminating species by exposure to products of the water vapor plasma. In other embodiments, the backsides 928B also include conductive surfaces (not shown) such as contact pads or exposed ends of through substrate vias (TSVs), in which case exposure to the products of water vapor plasma also inhibit, prevent or remove oxides from the conductive surfaces, as described above.

As shown in FIG. 9D, at block 808, a third element such as a third semiconductor element 950 having a prepared bonding surface is directly bonded to each of the backsides 928B of the second semiconductor elements 920. The third semiconductor elements 950 include a substrate 952 (which can include bulk or single crystal semiconductor material as well as BEOL layers; other elements can include a singulated package, or a substrate having a bonding surface comprising of an RDL layer with conductive features), a dielectric layer 954, and one or more conductive features 956 formed in the dielectric layer 954. In the illustrated embodiment, the third semiconductor elements 950 are directly bonded to the backsides 928B such that the dielectric layers 954 and the conductive features 956 face towards the backsides 928B and at least the dielectric layers 954 are directly bonded to the backsides 928B without an intervening adhesive. Block 808 can include initial room temperature direct bonding of non-conductive surfaces and subsequent anneal. Block 808 can represent direct hybrid bonding where the conductive features 956 are bonded to backside conductive features (not shown) of the second semiconductor elements 920, in which case a gap between corresponding conductors can be bridged by thermal expansion during anneal. In some embodiments, before directly bonding the third semiconductor element 950 to the backsides 928B, the third semiconductor element 950 is prepared for direct bonding, where preparing the third semiconductor element 950 for direct bonding includes exposing the dielectric layer 954 to the products of a water vapor plasma. In other embodiments, the third semiconductor element is prepared for direct bonding using a different process.

In some embodiments, after annealing the bonded structure, the bonded structure can be singulated using any suitable method, including, but not limited to, sawing, RIE, wet etching, molecular ion beam, leaser singulation, or a combination thereof. The singulated portion of the bonded structure can comprise one or more stacks of the directly bonded second and third semiconductor elements 920, 950 directly bonded to a singulated portion of the semiconductor element 910. In some embodiments, the stack(s) of second and third semiconductor elements 920, 950 bonded to the singulated portion of the semiconductor element 910 can be smaller (e.g., can have a smaller footprint) than the singulated portion of the semiconductor element 910. In some embodiments, multiple stacks of the directly bonded second and third semiconductor elements 920, 950 can be bonded to the singulated portion of the semiconductor element 910. For example, in some embodiments, multiple stacks of the directly bonded second and third semiconductor elements 920, 930 are directly bonded to the prepared bonding surface of a singulated portion of the semiconductor element 910 (e.g., the surface on which the frontsides 928A are directly bonded to). In some embodiments, after annealing the bonded structure, some or all of the bonded structure can be encapsulated in a polymeric layer prior to the bonded structure being singulated. In some embodiments, the singulated bonded structure can be encapsulated with a molding layer. In some embodiments, the backsides of the third semiconductor elements 950 (e.g., the sides of the third semiconductor elements 950 that are not directly bonded to the second semiconductor elements 920) can be prepared for bonding (e.g., direct bonding) of additional semiconductor elements.

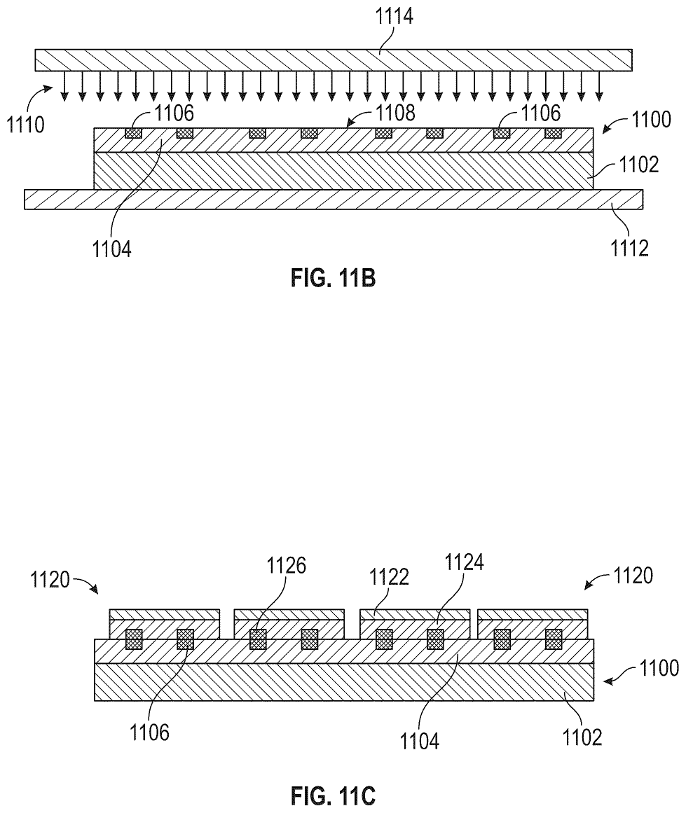

FIG. 10 is a flowchart illustrating an alternative bonding process 1000 that includes exposing an element that includes a polymeric material to the products of a water vapor plasma. FIGS. 11A-11C are schematic side sectional views of the element at various blocks of the bonding process 1000 shown in FIG. 10. Unless otherwise noted, features or blocks of FIGS. 10 and 11A-11C may be the same as or generally similar to features or blocks of FIGS. 2-9.

As shown in FIG. 11A, at block 1002, an element 1100 is provided. The element 1100 comprises a substrate 1102, a dielectric layer 1104, and one or more conductive features 1106 formed in the dielectric layer 1104. The element 1100 includes a bonding surface 1108 formed at the dielectric layer 1104. In some embodiments, the substrate 1102 can comprise polymeric material, such as a flex substrate. In some embodiments, the substrate 1102 comprises a package with one or more partially or fully embedded dies. In other embodiments, the substrate 1102 can comprise a temporary substrate having a bonding surface comprising a BEOL layer or an RDL layer with one or more conductive features. In still other embodiments, the conductive features 1106 can be adapted for hybrid bonding and can be partially embedded in the bonding surface of the substrate 1102.

As shown in FIG. 11B, at block 1004, the surface 1108 of the dielectric layer 1104 is exposed to products of a water vapor plasma 1110. The element 1100 is mounted to a carrier 1112 and the products of the water vapor plasma 1110 are provided to the bonding surface 1108 in a plasma chamber. In some embodiments, the products of the water vapor plasma 1110 are provided to the bonding surface 1108 using a plasma distribution system 1114. As described in greater detail elsewhere in the specification, the products of the water vapor plasma 1110 can comprise reactive species of oxygen and hydrogen, such as oxygen ions, atomic oxygen, hydroxy ions, hydrogen ions, and atomic hydrogen. In some embodiments, the water vapor plasma is also configured to clean the surface of the conductive features 1106. In some embodiments, the surface 1108 of the dielectric layer 1104 is also exposed to plasma products of a carrier gas, which can include additional terminating species such as nitrogen or fluorine. In some embodiments, after exposing the bonding surface 1108 of the dielectric layer 1104 to the water vapor plasma, the bonding surface 1108 is cleaned with DI water or another suitable solvent and then dried.

As shown in FIG. 11C, at block 1006, one or more elements, such as element 1120, are bonded to the prepared bonding surface 1108. In the illustrated embodiment, the element 1120 is provided in singulated die form. In other embodiments, however, the element 1120 is provided in wafer form. In such embodiments, only the single element 1120 may be bonded to the element 1100. The element 1120 includes a substrate 1122 (which as noted above can include a bulk or single crystal semiconductor material as well as BEOL layers; other elements can include a singulated dielectric layer, or a singulated package), a dielectric layer 1124, and one or more conductive features formed in the dielectric layer 1124. As described above, employing products of water plasma can lower thermal budgets, which can be particularly advantageous for directly bonding substrates that include temperature sensitive polymer materials, such as flex.

In some embodiments, the bonded structure (e.g., the structure formed from the element 1100 and the one or more elements 1120 bonded to the element 1100) can be singulated using any suitable method, including, but not limited to, sawing, RIE, wet etching, molecular ion beam, leaser singulation, or a combination thereof. The singulated portion of the bonded structure can comprise one or more of the elements 1120 bonded to a singulated portion of the element 1100. In some embodiments, the element(s) 1120 bonded to the singulated portion of the element 1100 can be smaller (e.g., can have a smaller footprint) than the singulated portion of the element 1100. In some embodiments, multiple elements 1120 can be bonded to the singulated portion of the element 1100. For example, in some embodiments, multiple elements 1120 are bonded to the prepared bonding surface (e.g., bonding surface 1108, shown in FIGS. 11A and 11B) of a singulated portion of the element 1100. The multiple elements 1120 can be spaced apart from each other by a specified pitch. In some embodiments, some or all of the bonded structure can be encapsulated in a polymeric layer prior to the bonded structure being singulated. In some embodiments, the singulated bonded structure can be encapsulated with a molding layer. In some embodiments, the backsides of the elements 1120 (e.g., the sides elements 1120 that are not bonded to the singulated portion of the element 1100) can be prepared for bonding (e.g., direct bonding) of additional elements.

In accordance with one aspect, a process is provided. The process can include providing an element having a dielectric bonding surface and a conductive feature exposed at the dielectric bonding surface. The dielectric bonding surface having a planarity suitable for direct bonding. The process also includes exposing the dielectric bonding surface to products of a water vapor plasma prior to direct bonding.

In some embodiments, the process further includes cleaning and drying the dielectric bonding surface. In some embodiments, the element includes a first element, the dielectric bonding surface includes a first dielectric bonding surface, and the conductive feature includes a first conductive feature, where the process further includes providing a second element having a second dielectric bonding surface and a second conductive feature exposed at the second dielectric bonding surface, where the second dielectric bonding surface has a planarity suitable for direct bonding. The process also includes directly bonding the first element to the second element by directly bonding the first dielectric bonding surface to the second dielectric bonding surface. In some embodiments, the process also includes, after providing the second element but before directly bonding the first element to the second element, exposing the second dielectric bonding surface to products of another water vapor plasma. In some embodiments, the process also includes, after directly bonding the first element to the second element, annealing the directly bonded first and second elements to form metallic bonds between the first and second conductive features. In some embodiments, the process also includes, before directly bonding the first element to the second element, positioning the second element over the first element such that the first dielectric bonding surface is facing the second dielectric bonding surface and the first conductive feature is aligned with the second conductive feature. In some embodiments, the first conductive feature is recessed below the first dielectric bonding surface and the second conductive feature is recessed below the second dielectric bonding surface. In some embodiments, before the directly bonded first and second elements are annealed, a distance between the first and second conductive features is 12 nm or less. In some embodiments, annealing the directly bonded first and second elements includes annealing the first and second elements at a temperature less than 250° C. In some embodiments, annealing the first and second elements at a temperature less than 250° C. includes annealing the first and second elements at a temperature less than 200° C. In some embodiments, directly bonding the first dielectric bonding surface to the second dielectric bonding surface includes directly bonding the first and second dielectric bonding surfaces at room temperature. In some embodiments, the process also includes forming a protective layer over a back surface of the first element. The process also includes after directly bonding the first element to the second element, singulating the directly bonded first and second elements into a plurality of bonded dies. In some embodiments, exposing the dielectric bonding surface to the products of the water vapor plasma includes exposing the dielectric bonding surface to the products of a mixture of the water vapor plasma and a carrier gas. In some embodiments, the conductive feature includes copper.

In accordance with another aspect, a process is provided. The process includes providing a first element having a first dielectric bonding surface and a first conductive feature exposed at the first dielectric bonding surface and supplying products of a water vapor plasma to the first element and exposing the first dielectric bonding surface to the products of the water vapor plasma. The process also includes providing a second element having a second dielectric bonding surface and a second conductive feature exposed at the second dielectric bonding surface and directly hybrid bonding the first element to the second element after supplying the products of the water vapor plasma to the first element.

In some embodiments, supplying the products of the water vapor plasma to the first element includes supplying the products of a mixture of water vapor plasma and a carrier gas to the first element. In some embodiments, exposing the first dielectric bonding surface to the products of the water vapor plasma includes supplying water vapor to a plasma generation apparatus without supplying additional reactive species to the plasma generation apparatus. In some embodiments, the process also includes, after providing the second element, supplying products of another water vapor plasma to the second element and exposing the second dielectric bonding surface to the products of the another water vapor plasma. In some embodiments, the process also includes, before supplying the products of the water vapor plasma to the first element, supplying products of an oxygen plasma to the first element to expose the first dielectric bonding surface to the products of the oxygen plasma. In some embodiments, supplying the products of the oxygen plasma to the first element includes supplying products of an oxygen and water vapor plasma to the first element. In some embodiments, supplying the products of the oxygen plasma to the first element includes supplying oxygen gas to a plasma generation apparatus without supplying water vapor to the plasma generation apparatus. In some embodiments, directly hybrid bonding the first element to the second element includes room temperature bonding the first dielectric bonding surface to the second dielectric bonding surface to form an initial bonded structure and subsequently annealing the initial bonded structure to form metallic bonds between the first and second conductive features.

In accordance with another aspect, a method of forming a bonded structure is provided. The method includes exposing a surface of a first element to products of a water vapor plasma and directly bonding the surface of the first element to a bonding surface of a second element.

In some embodiments, the surface includes a first non-conductive field region and a first conductive feature, and wherein the bonding surface of the second element includes a second non-conductive field region and a second conductive feature. In some embodiments, directly bonding the surface of the first element to the bonding surface of the second element includes directly hybrid bonding. In some embodiments, the method also includes, after exposing the surface of the first element to the water vapor plasma, drying the surface of the first element. In some embodiments, the method also includes, before directly bonding the surface of the first element to the bonding surface of the second element, exposing the bonding surface of the second element to products of another water vapor plasma. In some embodiments, directly bonding the surface of the first element to the bonding surface of the second element includes annealing the directly bonded first and second elements to form metallic bonds between conductive features on the first and second elements. In some embodiments, annealing the directly bonded first and second elements includes annealing the first and second elements at a temperature less than 200° C.

In accordance with another aspect, a method of forming a bonded structure is provided. The method includes exposing a first bonding surface of a first element to products of a water vapor plasma and directly bonding the first bonding surface to a second bonding surface of a second element.

In some embodiments, the first bonding surface includes a first non-conductive field region and a first conductive feature and wherein the second bonding surface includes a second non-conductive field region and a second conductive feature.

Unless the context clearly requires otherwise, throughout the description and the claims, the words “comprise.” “comprising.” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above.” “below.” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might.” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A process, comprising:
providing an element having a dielectric bonding surface and a conductive feature exposed at the dielectric bonding surface, the dielectric bonding surface having a planarity suitable for direct bonding; and
exposing the dielectric bonding surface to products of a water vapor plasma prior to direct bonding.

2. (canceled)

3. The process of claim 1 wherein the element comprises a first element, the dielectric bonding surface comprises a first dielectric bonding surface, and the conductive feature comprises a first conductive feature, the process further comprising:
providing a second element having a second dielectric bonding surface and a second conductive feature exposed at the second dielectric bonding surface, wherein the second dielectric bonding surface has a planarity suitable for direct bonding; and
directly bonding the first element to the second element by directly bonding the first dielectric bonding surface to the second dielectric bonding surface.

4. (canceled)

5. The process of claim 3, further comprising:
after directly bonding the first element to the second element, annealing the directly bonded first and second elements to form metallic bonds between the first and second conductive features.

6. The process of claim 5, further comprising:
before directly bonding the first element to the second element, positioning the second element over the first element such that the first dielectric bonding surface is facing the second dielectric bonding surface and the first conductive feature is aligned with the second conductive feature.

7. The process of claim 6, wherein the first conductive feature is recessed below the first dielectric bonding surface and the second conductive feature is recessed below the second dielectric bonding surface.

8. The process of claim 7, wherein, before annealing the directly bonded first and second elements, a distance between the first and second conductive features is 12 nm or less.

9. The process of claim 8, wherein annealing the directly bonded first and second elements comprises annealing the first and second elements at a temperature less than 200° C.

10. (canceled)

11. (canceled)

12. The process of claim 3, further comprising:
forming a protective layer over a back surface of the first element; and
after directly bonding the first element to the second element, singulating the directly bonded first and second elements into a plurality of bonded dies.

13. (canceled)

14. The process of claim 1, wherein the conductive feature comprises copper.

15. A process, comprising:
providing a first element having a first dielectric bonding surface and a first conductive feature exposed at the first dielectric bonding surface;
supplying products of a water vapor plasma to the first element and exposing the first dielectric bonding surface to the products of the water vapor plasma;
providing a second element having a second dielectric bonding surface and a second conductive feature exposed at the second dielectric bonding surface; and
directly hybrid bonding the first element to the second element after supplying the products of the water vapor plasma to the first element.

16. The process of claim 15, wherein supplying the products of the water vapor plasma to the first element comprises supplying the products of a mixture of water vapor plasma and a carrier gas to the first element.

17. The process of claim 15, wherein exposing the first dielectric bonding surface to the products of the water vapor plasma comprises supplying water vapor to a plasma generation apparatus without supplying additional reactive species to the plasma generation apparatus.

18. (canceled)

19. The process of claim 15, further comprising:
before supplying the products of the water vapor plasma to the first element, supplying products of an oxygen plasma to the first element to expose the first dielectric bonding surface to the products of the oxygen plasma.

20. (canceled)

21. (canceled)

22. The process of claim 15, wherein directly hybrid bonding the first element to the second element comprises room temperature bonding the first dielectric bonding surface to the second dielectric bonding surface to form an initial bonded structure and subsequently annealing the initial bonded structure to form metallic bonds between the first and second conductive features.

23. A method of forming a bonded structure, the method comprising:
exposing a surface of a first element to products of a water vapor plasma; and
directly bonding the surface of the first element to a bonding surface of a second element.

24. The method of claim 23, wherein the surface comprises a first non-conductive field region and a first conductive feature, and wherein the bonding surface of the second element comprises a second non-conductive field region and a second conductive feature.

25. The method of claim 24, wherein directly bonding the surface of the first element to the bonding surface of the second element comprises directly hybrid bonding.

26. (canceled)

27. The method of claim 23, further comprising:
before directly bonding the surface of the first element to the bonding surface of the second element, exposing the bonding surface of the second element to products of another water vapor plasma.

28. The method of claim 23, wherein directly bonding the surface of the first element to the bonding surface of the second element comprises annealing the directly bonded first and second elements to form metallic bonds between conductive features on the first and second elements.

29. The method of claim 28, wherein annealing the directly bonded first and second elements comprises annealing the first and second elements at a temperature less than 200° C.

30. (canceled)

31. (canceled)
